(19) United States
(12) Patent Application Publication
(10) Pub. No.: US 2016/0291470 A1
(43) Pub. Date: Oct. 6, 2016

(54) PHOTOSENSITIVE POLYSILOXANE COMPOSITION, PROTECTING FILM, AND ELEMENT HAVING PROTECTIVE FILM

(71) Applicant: Chi Mei Corporation, Tainan City (TW)

(72) Inventors: Ming-Ju Wu, Tainan City (TW); Chun-An Shih, Tainan City (TW)

(21) Appl. No.: 15/077,909

(22) Filed: Mar. 23, 2016

(30) Foreign Application Priority Data
Mar. 31, 2015 (TW) 104110487

(51) Int. Cl. G03F 7/075; G03F 7/40; G03F 7/32; G03F 7/16; G03F 7/20

(52) U.S. Cl. CPC G03F 7/0757; G03F 7/168; G03F 7/20; G03F 7/32; G03F 7/40

(57) ABSTRACT

A photosensitive polysiloxane composition having good adhesion during development, a protective film, and an element having the protective film are provided. The photosensitive polysiloxane composition includes a polysiloxane (A), an o-naphthoquinonediazidesulfonate (B), and a solvent (C). The polysiloxane (A) is obtained via the polycondensation of a monomer component, wherein the monomer component includes a titanium-containing compound (a-1) and a silane monomer (a-2) represented by formula (2). The titanium-containing compound (a-1) is selected from the group consisting of a compound represented by formula (1-1) and a hydrolyzable titanium dimer.

Ti(R¹)ₐ(R²)₄₋ₐ formula (1-1)

Si(R^{a})_{w}(OR^{b})_{4-w} formula (2)

### CROSS-REFERENCE TO RELATED APPLICATION

This application claims the priority benefit of Taiwan application serial no. 104110487, filed on Mar. 31, 2015. The entirety of the above-mentioned patent application is hereby incorporated by reference herein and made a part of this specification.

### BACKGROUND OF THE INVENTION

1. Field of the Invention

The invention relates to a photosensitive polysiloxane composition, a protective film, and an element having the protective film. More particularly, the invention relates to a photosensitive polysiloxane composition having good adhesion during development, a protective film formed thereby, and an element having the protective film.

2. Description of Related Art

In recent years, with the development of the semiconductor industry, liquid crystal displays (LCDs), and organic electro-luminescence displays (OLEDs), and the resulting demand for size reduction, the photolithography process has become a very important topic. In the photolithography process, the desired pattern needs to be finer so as to achieve the goal of size reduction. In general, the finer pattern is formed by performing exposure and development on a positive photosensitive polysiloxane composition having high resolution and high photosensitivity. It should be mentioned that, polysiloxane is generally the main component of the positive photosensitive polysiloxane composition.

In the LCD or the OELD, an interlayer insulating film is generally disposed between the layered wirings. Since the steps needed to obtain a pattern shape for a photosensitive material are less, and at the same time, the flatness of the obtained insulating film is good, the photosensitive material is been extensively used as a material for forming the interlayer insulating film.

However, since the refractive index of polysiloxane is lower than that of an acrylic resin, when coated on the surfaces of other layers such as indium tin oxide (ITO), the ITO pattern is readily visible due to the large difference in the refractive index, thus resulting in a drawback of low visibility for the LCD screen.

Japanese Unexamined Patent Application Publication No. 2008-24832 discloses a high-refractive index material containing a siloxane compound, wherein the siloxane has an aromatic hydrocarbon group. However, a material capable of forming a cured film having a high refractive index has been more desired in recent years. The siloxane material having a high refractive index is, for instance, a siloxane resin composition obtained via the hydrolysis and condensation reaction of alkoxy silane in the presence of a metal compound particle. However, the sensitivity of the siloxane resin composition during exposure is insufficient, and the resolution is poor due to residue formed during development. That is, the adhesion of the siloxane resin composition during development is poor.

Therefore, how to reach the demands of current industries for adhesion during development is an object being actively researched for those skilled in the art.

### SUMMARY OF THE INVENTION

Accordingly, the invention provides a photosensitive polysiloxane composition having good adhesion during development, a protective film, and an element having the protective film.

The invention provides a photosensitive polysiloxane composition including a polysiloxane (A), an o-naphthoquinonediazidesulfonate (B), and a solvent (C). The polysiloxane (A) is obtained via the polycondensation of a monomer component, wherein the monomer component includes a titanium-containing compound (a-1) and a silane monomer (a-2) represented by formula (2). The titanium-containing compound (a-1) is selected from the group consisting of a compound represented by formula (1-1) and a hydrolyzable titanium dimer.

Ti(R¹)ₐ(R²)₄₋ₐ formula (1-1)

In formula (1-1), R¹ each independently represents an organic group having an alkyl group, an aryl group, a halogenated alkyl group, a halogenated aryl group, an alkenyl group, an epoxy group, an acryloyl group, a methacryloyl group, a mercapto group, an amine group, or a cyano group, and the organic group is bonded with a titanium atom via a Ti—C bond; R² each independently represents an alkoxy group, an acyloxy group, or a halogen atom; a represents an integer of 0 to 2,

Si(R^{a})_{w}(OR^{b})_{4-w} formula (2)

In formula (2), R^{a} each independently represents a hydrogen atom, a C₁ to C₁₀ alkyl group, a C₂ to C₁₀ alkenyl group, a C₆ to C₁₅ aryl group, an alkyl group containing an anhydride group, an alkyl group containing an epoxy group, or an alkoxy group containing an epoxy group; R^{b} each independently represents a hydrogen atom, a C₁ to C₆ alkyl group, a C₁ to C₆ acyl group, or a C₆ to C₁₅ aryl group; w represents an integer of 1 to 3.

In an embodiment of the invention, in formula (2), at least one R^{a} represents an alkyl group containing an anhydride group, an alkyl group containing an epoxy group, or an alkoxy group containing an epoxy group.

In an embodiment of the invention, the solvent used in the polycondensation of the polysiloxane (A) includes a ketone solvent.

In an embodiment of the invention, the weight-average molecular weight of the polysiloxane (A) is 600 to 4000.

In an embodiment of the invention, based on 100 parts by weight of the polysiloxane (A), the usage amount of the o-naphthoquinonediazidesulfonate (B) is 1 part by weight to 35 parts by weight, and the usage amount of the solvent (C) is 100 parts by weight to 1200 parts by weight.

The invention further provides a protective film formed by coating the above photosensitive polysiloxane composition on an element, and then performing pre-bake, exposure, development, and post-bake.

The invention further provides an element having a protective film, including an element and the above protective film, wherein the protective film covers the element.

Based on the above, since the photosensitive polysiloxane composition of the invention contains a polysiloxane obtained via the polycondensation of a specific titanium-containing compound, the adhesion thereof during development is good, and the photosensitive polysiloxane composition is suitable for forming a protective film.

To make the above features and advantages of the invention more comprehensible, several embodiments are described in detail as follows.

### DESCRIPTION OF THE EMBODIMENTS

### Photosensitive Polysiloxane Composition

The invention provides a photosensitive polysiloxane composition including a polysiloxane (A), an o-naphthoquinonediazidesulfonate (B), and a solvent (C). Moreover, the photosensitive polysiloxane composition can further include an additive (D) if needed.

In the following, the individual components used in the photosensitive polysiloxane composition of the invention are described in detail.

It should be mentioned that, in the following, (meth)acrylic acid represents acrylic acid and/or methacrylic acid, and (meth)acrylate represents acrylate and/or methacrylate. Similarly, (meth)acryloyl group represents acryloyl group and/or methacryloyl group.

### Polysiloxane (A)

The polysiloxane (A) is obtained via the polycondensation of a monomer component, wherein the monomer component includes a titanium-containing compound (a-1) and a silane monomer (a-2). Moreover, the monomer component can further include a siloxane prepolymer (a-3) or a silica particle (a-4) other than the titanium-containing compound (a-1) and the silane monomer (a-2), or a combination thereof, but is not limited thereto. Each component of the monomer component synthesizing the polysiloxane (A) and the reaction steps and conditions of the polycondensation are further described below.

Titanium-Containing Compound (a-1)

The titanium-containing compound (a-1) is selected from the group consisting of a compound represented by formula (1-1) and a hydrolyzable titanium dimer.

Ti(R¹)ₐ(R²)₄₋ₐ formula (1-1)

In formula (1-1), R¹ each independently represents an organic group having an alkyl group, an aryl group, a halogenated alkyl group, a halogenated aryl group, an alkenyl group, an epoxy group, an acryloyl group, a methacryloyl group, a mercapto group, an amine group, or a cyano group, and the organic group is bonded with a titanium atom via a Ti—C bond; R² each independently represents an alkoxy group, an acyloxy group, or a halogen atom; a represents an integer of 0 to 2.

In the compound represented by formula (1-1), a compound for which a represents 0 is preferably used.

The alkyl group can be a straight-chain or branched C₁ to C₁₀ alkyl group, such as a methyl group, an ethyl group, an n-propyl group, an isopropyl group, an n-butyl group, an isobutyl group, a sec-butyl group, a tert-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, or a 1-ethyl-2-methyl-n-propyl group.

Moreover, the alkyl group can also be a C₁ to C₁₀ cyclic alkyl group, such as a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-isopropyl-cyclopropyl group, a 2-isopropyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, or a 2-ethyl-3-methyl-cyclopropyl group.

Moreover, the C₁ to C₁₀ alkylene group can be an alkylene group derived from the above alkyl group.

The aryl group can be a C₆ to C₂₀ aryl group, such as a phenyl group, an o-methylphenyl group, an m-methylphenyl group, a p-methylphenyl, an o-chlorophenyl group, an m-chlorophenyl group, a p-chlorophenyl group, an o-fluorophenyl group, a p-mercaptophenyl group, an o-methoxyphenyl group, a p-methoxyphenyl group, a p-aminophenyl group, a p-cyanophenyl group, an α-naphthyl group, β-naphthyl group, an o-biphenyl group, an m-biphenyl group, a p-biphenyl group, a 1-anthryl group, a 2-anthryl group, a 9-anthryl group, a 1-phenanthryl group, a 2-phenanthryl group, a 3-phenanthryl group, a 4-phenanthryl group, or a 9-phenanthryl group.

The alkenyl group can be a C₂ to C₁₀ alkenyl group, such as a vinyl group, a 1-propenyl group, a 2-propenyl group, a 1-methyl-1-vinyl group, a 1-butenyl group, a 2-butenyl group, a 3-butenyl group, a 2-methyl-1-propenyl group, a 2-methyl-2-propenyl group, a 1-ethylvinyl group, a 1-methyl-1-propenyl group, a 1-methyl-2-propenyl group, a 1-pentenyl group, a 2-pentenyl group, a 3-pentenyl group, a 4-pentenyl group, a 1-n-propylvinyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-isopropyl vinyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butyl vinyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-sec-butylvinyl group, a 1,3-dimethyl-1-butenyl group, a 1,3-dimethyl-2-butenyl group, a 1,3-dimethyl-3-butenyl group, a 1-isobutylvinyl group, a 2,2-dimethyl-3-butenyl group, a 2,3-dimethyl-1-butenyl group, a 2,3-dimethyl-2-butenyl group, a 2,3-dimethyl-3-butenyl group, a 2-isopropyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-tert-butylvinyl group, a 1-methyl-1-ethyl-2-propenyl group, a 1-ethyl-2-methyl-1-propenyl group, a 1-ethyl-2-methyl-2-propenyl group, a 1-isopropyl-1-propenyl group, a 1-isopropyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methyl-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methyl-cyclopentyl group, a 1-cyclohexenyl group, a 2-cyclohexenyl group, or a 3-cyclohexenyl group.

Moreover, the halogenated alkyl group and the halogenated aryl group are, for instance, an alkyl group or an aryl group for which one or more hydrogen atoms are substituted by halogen atoms such as fluorine atoms, chlorine atoms, bromine atoms, or iodine atoms in the above alkyl group or aryl group.

The organic group having an epoxy group is, for instance, a glycidoxymethyl group, a glycidoxyethyl group, a glycidoxypropyl group, a glycidoxybutyl group, or an epoxycyclohexyl group.

The organic group having an acryloyl group is, for instance, an acryloyl methyl group, an acryloyl ethyl group, or an acryloyl propyl group.

The organic group having a methacryloyl group is, for instance, a methacryloyl methyl group, a methacryloyl ethyl group, or a methacryloyl propyl group.

The organic group having a mercapto group is, for instance, an ethyl mercapto group, a butyl mercapto group, a hexyl mercapto group, or an octyl mercapto group.

The organic group having an amine group is, for instance, an aminomethyl group, an aminoethyl group, or an aminopropyl group.

The organic group having a cyano group is, for instance, a cyanoethyl group or a cyanopropyl group.

The organic group having a sulfonyl group is, for instance, a methyl sulfonyl group, an allyl sulfonyl group, or a phenyl sulfonyl group.

The alkoxy group can be a C₁ to C₃₀ alkoxy group, and is preferably a C₁ to C₁₀ alkoxy group such as a methoxy group, an ethoxy group, an n-propoxy group, an isopropoxy group, an n-butoxy group, an isobutoxy group, a sec-butoxy group, a tert-butoxy group, an n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, or a phenoxy group.

The acyloxy group can be a C₁ to C₃₀ acyloxy group, preferably a C₁ to C₁₀ acyloxy group such as a methyl carbonyloxy group, an ethyl carbonyloxy group, an n-propyl carbonyloxy group, an isopropyl carbonyloxy group, a cyclopropyl carbonyloxy group, an n-butyl carbonyloxy group, an isobutyl carbonyloxy group, a sec-butyl carbonyloxy group, a tert-butyl carbonyloxy group, a cyclobutyl carbonyloxy group, a 1-methyl-cyclopropyl carbonyloxy group, a 2-methyl-cyclopropyl carbonyloxy group, an n-pentyl carbonyloxy group, a 1-methyl-n-butyl carbonyloxy group, a 2-methyl-n-butyl carbonyloxy group, a 3-methyl-n-butyl carbonyloxy group, a 1,1-dimethyl-n-propyl carbonyloxy group, a 1,2-dimethyl-n-propyl carbonyloxy group, a 2,2-dimethyl-n-propyl carbonyloxy group, a 1-ethyl-n-propyl carbonyloxy group, a cyclopentyl carbonyloxy group, a 1-methyl-cyclobutyl carbonyloxy group, a 2-methyl-cyclobutyl carbonyloxy group, a 3-methyl-cyclobutyl carbonyloxy group, a 1,2-dimethyl-cyclopropyl carbonyloxy group, a 2,3-dimethyl-cyclopropyl carbonyloxy group, a 1-ethyl-cyclopropyl carbonyloxy group, a 2-ethyl-cyclopropyl carbonyloxy group, an n-hexyl carbonyloxy group, a 1-methyl-n-pentyl-carbonyloxy group, a 2-methyl-n-pentyl-carbonyloxy group, a 3-methyl-n-pentyl-carbonyloxy group, a 4-methyl-n-pentyl-carbonyloxy group, a 1,1-dimethyl-n-butyl carbonyloxy group, a 1,2-dimethyl-n-butyl carbonyloxy group, a 1,3-dimethyl-n-butyl carbonyloxy group, a 2,2-dimethyl-n-butyl carbonyloxy group, a 2,3-dimethyl-n-butyl carbonyloxy group, a 3,3-dimethyl-n-butyl carbonyloxy group, a 1-ethyl-n-butyl carbonyloxy group, a 2-ethyl-n-butyl carbonyloxy group, a 1,1,2-trimethyl-n-propyl carbonyloxy group, a 1,2,2-trimethyl-n-propyl carbonyloxy group, a 1-ethyl-1-methyl-n-propyl carbonyloxy group, a 1-ethyl-2-methyl-n-propyl carbonyloxy group, a cyclohexyl carbonyloxy group, a 1-methyl-cyclopentyl carbonyloxy group, a 2-methyl-cyclopentyl carbonyloxy group, a 3-methyl-cyclopentyl carbonyloxy group, a 1-ethyl-cyclobutyl carbonyloxy group, a 2-ethyl-cyclobutyl carbonyloxy group, a 3-ethyl-cyclobutyl carbonyloxy group, a 1,2-dimethyl-cyclobutyl carbonyloxy group, a 1,3-dimethyl-cyclobutyl carbonyloxy group, a 2,2-dimethyl-cyclobutyl carbonyloxy group, a 2,3-dimethyl-cyclobutyl carbonyloxy group, a 2,4-dimethyl-cyclobutyl carbonyloxy group, a 3,3-dimethyl-cyclobutyl carbonyloxy group, a 1-n-propyl-cyclopropyl carbonyloxy group, a 2-n-propyl-cyclopropyl carbonyloxy group, a 1-isopropyl-cyclopropyl carbonyloxy group, a 2-isopropyl-cyclopropyl carbonyloxy group, a 1,2,2-trimethyl-cyclopropyl carbonyloxy group, a 1,2,3-trimethyl-cyclopropyl carbonyloxy group, a 2,2,3-trimethyl-cyclopropyl carbonyloxy group, a 1-ethyl-2-methyl-cyclopropyl carbonyloxy group, a 2-ethyl-1-methyl-cyclopropyl carbonyloxy group, a 2-ethyl-2-methyl-cyclopropyl carbonyloxy group, or [[2-(butoxycarbonyl)phenyl]carbonyl]oxy.

The halogen atom is, for instance, a fluorine atom, a chloro group, a bromine atom, or an iodine atom.

In the compound represented by formula (1-1) (hydrolyzable titanium compound), if R² is an alkoxy group, then R² can be the same alkoxy groups or different alkoxy groups. Moreover, if R² is an acyloxy group or a halogen atom, then R² can be the same acyloxy groups or halogen atoms or different acyloxy groups or halogen atoms.

Specific examples of the compound (hydrolyzable titanium compound) represented by formula (1-1) include titanium alkoxide such as tetramethoxy titanium, tetraethoxy titanium, tetraisopropoxy titanium, tetra-n-butoxy titanium, tetra-isobutyloxy titanium, titanium 2-ethyl hexoxide, tetra(methoxypropoxy)titanium, tetraphenoxy titanium, tetrabenzyloxy titanium, tetraphenylethoxy titanium, tetraphenoxyethoxy titanium, tetranaphthyloxy titanium, tetra-2-ethylhexoxy titanium, monoethoxy triisopropoxy titanium, diisopropoxy diisobutoxy titanium, allyloxy(polyethyleneoxy)triisopropoxy titanium, titanium chloride triisopropoxide, titanium dichloride diethoxide, 2-ethylhexanol titanium, titanium iodide triisopropoxide, tetramethoxide propanol titanium, tetramethyl phenol titanium, n-nonanol titanium, tetrastearyl alcohol titanium, or triisostearoyl acyl monoisopropanol titanium; acyloxy titanium such as tetramethyl carbonyloxy titanium, tetraethyl carbonyloxy titanium, tetra-n-propyl carbonyloxy titanium, tetraisopropyl carbonyloxy titanium, methylcarbonyloxy triethyl carbonyloxy titanium, or dibutoxybis[[[2-(butoxycarbonyl)phenyl]carbonyl]oxy]titanium(IV); titanium halide such as titanium tetrafluoride, titanium tetrachloride, titanium tetrabromide, or titanium tetraiodide; hydrolyzable alkyl alkoxy titanium such as triisopropoxide methyl titanium, triisopropoxide ethyl titanium, or triisobutoxide methyl titanium; or a combination of the compounds.

The hydrolyzable titanium dimer is formed by the dimerization of titanium alkoxide, titanium halide, and a titanium acyloxy group via a Ti—O—Ti bond. Specifically, the hydrolyzable titanium dimer is a compound represented by formula (1-2).

(R³)₃—Ti—O—Ti—(R³)₃ formula (1-2)

In formula (1-2), R³ each independently represents an alkoxy group, an acyloxy group, or a halogen atom.

Specific examples of the hydrolyzable titanium dimer include titanium butoxide dimer, titanium isobutoxide dimer, titanium propoxide dimer, or titanium isopropoxide dimer.

Specific examples of the titanium-containing compound (a-1) preferably include titanium isobutoxide, titanium 2-ethylhexyloxide, dibutoxy bis[[[2-(butoxycarbonyl)phenyl]carbonyl]oxy]titanium, titanium propoxide dimer, or a combination of the compounds.

Based on a total amount of 100 mol % of the monomer in the monomer component synthesizing the polysiloxane (A), the usage amount of the titanium-containing compound (a-1) is 10 mol % to 60 mol %, preferably 15 mol % to 55 mol %, and more preferably 20 mol % to 55 mol %. When the monomer component for synthesizing the polysiloxane (A) does not include the titanium-containing compound (a-1), then the adhesion of the photosensitive polysiloxane composition during development is poor.

Silane Monomer (a-2)

The silane monomer (a-2) is a compound represented by formula (2).

Si(R^{a})_{w}(OR^{b})_{4-w} formula (2)

In formula (2), R^{a} each independently represents a hydrogen atom, a C₁ to C₁₀ alkyl group, a C₂ to C₁₀ alkenyl group, a C₆ to C₁₅ aryl group, an alkyl group containing an anhydride group, an alkyl group containing an epoxy group, or an alkoxy group containing an epoxy group; R^{b} each independently represents a hydrogen atom, a C₁ to C₆ alkyl group, a C₁ to C₆ acyl group, or a C₆ to C₁₅ aryl group; w represents an integer of 1 to 3.

More specifically, when R^{a} in formula (2) represents a C₁ to C₁₀ alkyl group, specifically, R^{a} is, for instance, a methyl group, an ethyl group, an n-propyl group, an isopropyl group, an n-butyl group, a tert-butyl group, an n-hexyl group, or an n-decyl group. Moreover, R^{a} can also be an alkyl group having other substituents. Specifically, R^{a} is, for instance, trifluoromethyl, 3,3,3-trifluoropropyl, 3-aminopropyl, 3-mercaptopropyl, or 3-isocyanatepropyl.

When R^{a} in formula (2) represents a C₂ to C₁₀ alkenyl group, specifically, R^{a} is, for instance, a vinyl group. Moreover, R^{a} can also be an alkenyl group having other substituents. Specifically, R^{a} is, for instance, 3-acryoyloxypropyl or 3-methylacryloyloxypropyl.

When R^{a} in formula (2) represents a C₆ to C₁₅ aryl group, specifically, R^{a} is, for instance, a phenyl group, a tolyl group, or a naphthyl group. Moreover, R^{a} can also be an aryl group having other substituents. Specifically, R^{a} is, for instance, o-hydroxyphenyl, 1-(o-hydroxyphenyl)ethyl, 2-(o-hydroxyphenyl)ethyl, or 4-hydroxy-5-(p-hydroxyphenylcarbonyloxy)pentyl.

Moreover, R^{a} in formula (2) represents an alkyl group containing an anhydride group, wherein the alkyl group is preferably a C₁ to C₁₀ alkyl group. Specifically, the alkyl group containing an anhydride group is, for instance, ethyl succinic anhydride shown in formula (2-1), propyl succinic anhydride shown in formula (2-2), or propyl glutaric anhydride shown in formula (2-3). It should be mentioned that, the anhydride group is a group formed by the intramolecular dehydration of a dicarboxylic acid, wherein the dicarboxylic acid is, for instance, succinic acid or glutaric acid.

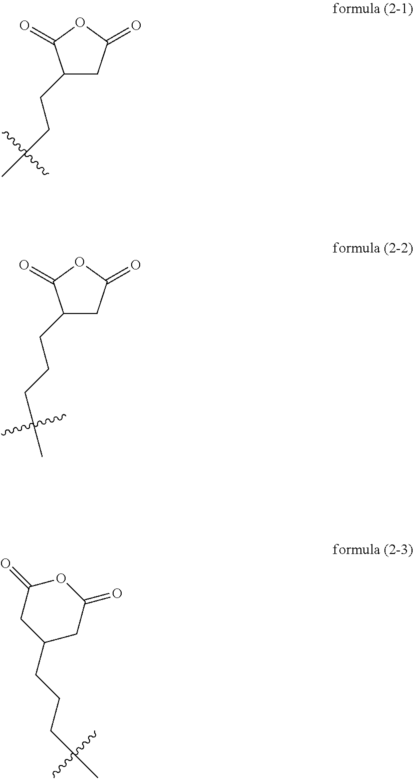 [SMILES: *CCC1CC(=O)OC1=O ; *CCCC1CC(=O)OC1=O ; *CCCC1CC(=O)OC(=O)C1]

Moreover, R^{a} in formula (2) represents an alkyl group containing an epoxy group, wherein the alkyl group is preferably a C₁ to C₁₀ alkyl group. Specifically, the alkyl group containing an epoxy group is, for instance, oxetanylpentyl or 2-(3,4-epoxycyclohexyl)ethyl. It should be mentioned that, the epoxy group is a group formed by the intramolecular dehydration of diol, wherein the diol is, for instance, propanediol, butanediol, or pentanediol.

R^{a} in formula (2) represents an alkoxy group containing an epoxy group, wherein the alkoxy group is preferably a C₁ to C₁₀ alkoxy group. Specifically, the alkoxy group containing an epoxy group is, for instance, glycidoxypropyl or 2-oxetanylbutoxy.

Moreover, when Rb in formula (2) represents a C₁ to C₆ alkyl group, specifically, R^{b} is, for instance, a methyl group, an ethyl group, an n-propyl group, an isopropyl group, or an n-butyl group. When R^{b} in formula (2) represents a C₁ to C₆ acyl group, specifically, R^{b} is, for instance, an acetyl group. When R^{b} in formula (2) represents a C₆ to C₁₅ aryl group, specifically, R^{b} is, for instance, a phenyl group.

In formula (2), w represents an integer of 1 to 3. When w represents 2 or 3, a plurality of R^{a} can be the same or different, and when w represents 1 or 2, a plurality of R^{b} can be the same or different.

Specific examples of the silane monomer (a-2) include a silane monomer without an anhydride group or an epoxy group, a silane monomer containing an anhydride group or an epoxy group, or a combination thereof. Specific examples of the silane monomer (a-2) preferably include a silane monomer containing an anhydride group or an epoxy group. In the photosensitive polysiloxane composition, when the monomer component synthesizing the polysiloxane (A) includes the silane monomer containing an anhydride group or an epoxy group, the adhesion of the photosensitive polysiloxane composition during development is better. In other words, in formula (2), at least one R^{a} representing an alkyl group containing an anhydride group, an alkyl group containing an epoxy group, or an alkoxy group containing an epoxy group is preferably present.

In the following, the silane monomer without an anhydride group or an epoxy group and the silane monomer containing an anhydride group or an epoxy group are described. In formula (2), when w=0, the silane monomer is a tetrafunctional silane monomer (i.e., a silane monomer having four hydrolyzable groups); when w=1, the silane monomer is a trifunctional silane monomer (i.e., a silane monomer having three hydrolyzable groups); when w=2, the silane monomer is a bifunctional silane monomer (i.e., a silane monomer having two hydrolyzable groups); and when w=3, the silane monomer is a monofunctional silane monomer (i.e., a silane monomer having one hydrolyzable group). It should be mentioned that, the hydrolyzable group refers to a group capable of being reacted in a hydrolysis reaction and bonded to silicon. For instance, the hydrolyzable group is, for instance, an alkoxy group, an acyloxy group, or a phenoxy group.

Specific examples of the silane monomer represented by formula (2) include, but are not limited to:
(1) a tetrafunctional silane monomer: tetramethoxysilane, tetraethoxysilane, tetraacetoxysilane, or tetraphenoxy silane;
(2) a trifunctional silane monomer: methyltrimethoxysilane (MTMS), methyltriethoxysilane, methyltriisopropoxysilane, methyltri-n-butoxysilane, ethyltrimethoxysilane, ethyltriethoxysilane, ethyltriisopropoxysilane, ethyltri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, phenyltrimethoxysilane (PTMS), phenyltriethoxysilane (PTES), p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, 3-mercaptopropyltrimethoxysilane, 3-acryloyloxypropyltrimethoxysilane, 3-methacryloyloxypropyltrimethoxysilane, or 3-methylacryloyloxypropyltriethoxysilane;
(3) a bifunctional silane monomer: dimethyldimethoxysilane (DMDMS), dimethyldiethoxysilane, dimethyldiacetyloxysilane, di-n-butyldimethoxysilane, or diphenyldimethoxysilane; or
(4) a monofunctional silane monomer: trimethylmethoxysilane or tri-n-butylethoxysilane . . . etc. The various silane monomers can be used alone or in multiple combinations.

Specific examples of the silane monomer without an anhydride group or an epoxy group preferably include methyltrimethoxysilane, dimethyldimethoxysilane, phenyltrimethoxysilane, phenyltriethoxysilane, or a combination of the compounds.

Specific examples of the silane monomer containing an anhydride group or an epoxy group include 3-glycidoxypropyltrimethoxysilane (TMS-GAA), 3-glycidoxypropyltriethoxysilane, 2-(3,4-epoxycyclohexyl) ethyl trimethoxy silane, 2-oxetanylbutoxypropyl triphenoxysilane, a commercial product made by Toagosei: 2-oxetanylbutoxypropyltrimethoxysilane (trade name: TMSOX-D), 2-oxetanylbutoxypropyltriethoxysilane (trade name: TESOX-D), 3-(triphenoxysilyl)propyl succinic anhydride, a commercial product made by Shin-Etsu Chemical: 3-(trimethoxysilyl)propyl succinic anhydride (trade name: X-12-967), a commercial product made by WACKER: 3-(triethoxysilyl)propyl succinic anhydride (trade name: GF-20), 3-(trimethoxysilyl)propyl glutaric anhydride (TMSG), 3-(triethoxysilyl)propyl glutaric anhydride, 3-(triphenoxysilyl)propyl glutaric anhydride, diisopropoxy-di(2-oxetanylbutoxy propyl)silane (DIDOS), di(3-oxetanylpentyl)dimethoxy silane, (di-n-butoxysilyl) di(propyl succinic anhydride), (dimethoxysilyl) di(ethyl succinic anhydride), 3-glycidoxypropyldimethylmethoxysilane, 3-glycidoxypropyl dimethylethoxysilane, di(2-oxetanylbutoxypentyl)-2-oxetanyl pentylethoxy silane, tri(2-oxetanylpentyl)methoxy silane, (phenoxysilyl) tri(propyl succinic anhydride), (methyl methoxysilyl) di(ethyl succinic anhydride), or a combination of the compounds.

Specific examples of the silane monomer containing an anhydride group or an epoxy group preferably include 3-(triethoxysilyl)propyl succinic anhydride, 3-(trimethoxysilyl)propyl glutaric anhydride, (dimethoxysilyl) di(ethyl succinic anhydride), 2-oxetanylbutoxypropyltrimethoxysilane, 2-oxetanylbutoxypropyltriethoxysilane, 2-(3,4-epoxycyclohexyl)ethyltrimethoxysilane, or a combination of the compounds.

Based on a total amount of 100 mol % of the monomer in the monomer component synthesizing the polysiloxane (A), the usage amount of the silane monomer (a-2) is 40 mol % to 90 mol %, preferably 35 mol % to 85 mol %, and more preferably 35 mol % to 80 mol %. When the monomer component synthesizing the polysiloxane (A) does not include the silane monomer (a-2), the photosensitive polysiloxane composition cannot be developed after exposure, which is unsatisfactory.

Siloxane Prepolymer (a-3)

The siloxane prepolymer (a-3) is a compound represented by formula (3).

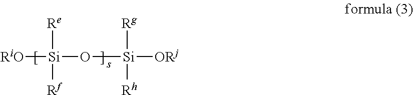

In formula (3), R^{e}, R^{f}, R^{g}, and R^{h} each independently represent a hydrogen atom, a C₁ to C₁₀ alkyl group, a C₂ to C₆ alkenyl group, or a C₆ to C₁₅ aryl group, wherein any one of the alkyl group, the alkenyl group, and the aryl group can optionally contain a substituent; Rⁱ and R^{j} each independently represent a hydrogen atom, a C₁ to C₆ alkyl group, a C₁ to C₁₀ acyl group, or a C₆ to C₁₅ aryl group, wherein any one of the alkyl group, the acyl group, and the aryl group can optionally contain a substituent; s represents an integer of 1 to 1000.

In formula (3), R^{e}, R^{f}, R^{g}, and R^{h} each independently represent a C₁ to C₁₀ alkyl group. For instance, R^{e}, R^{f}, R^{g}, and R^{h} are each independently a methyl group, an ethyl group, or an n-propyl group . . . etc. In formula (3), R^{e}, R^{f}, R^{g}, and R^{h} each independently represent a C₂ to C₁₀ alkenyl group. For instance, R^{e}, R^{f}, R^{g}, and R^{h} are each independently a vinyl group, an acryloyloxypropyl group, or a methacryloyloxypropyl group. In formula (3), R^{e}, R^{f}, R^{g}, and R^{h} each independently represent a C₆ to C₁₅ aryl group. For instance, R^{e}, R^{f}, R^{g}, and R^{h} are each independently a phenyl group, a tolyl group, or a naphthyl group . . . etc. It should be mentioned that, any one of the alkyl group, the alkenyl group, and the aryl group can optionally have a substituent.

In formula (3), Rⁱ and R^{j} each independently represent a C₁ to C₆ alkyl group. For instance, Rⁱ and R^{j} are each independently a methyl group, an ethyl group, an n-propyl group, an isopropyl group, or an n-butyl group. In formula (3), Rⁱ and R^{j} each independently represent a C₁ to C₆ acyl group such as an acetyl group. In formula (3), Rⁱ and R^{j} each independently represent a C₆ to C₁₅ aryl group such as a phenyl group. It should be mentioned that, any one of the alkyl group, the acyl group, and the aryl group can optionally have a substituent.

In formula (3), s can be an integer of 1 to 1000, preferably an integer of 3 to 300, and more preferably an integer of 5 to 200. When s is an integer of 2 to 1000, R^{e} is each the same or a different group, and R^{f} is each the same or a different group.

Specific examples of the siloxane prepolymer (a-3) include, but are not limited to, 1,1,3,3-tetramethyl-1,3-dimethoxydisiloxane, 1,1,3,3-tetramethyl-1,3-diethoxydisiloxane, 1,1,3,3-tetraethyl-1,3-diethoxydisiloxane, or a commercial product (such as DMS-S12 (molecular weight: 400 to 700), DMS-S15 (molecular weight: 1500 to 2000), DMS-S21 (molecular weight: 4200), DMS-S27 (molecular weight: 18000), DMS-S31 (molecular weight: 26000), DMS-S32 (molecular weight: 36000), DMS-S33 (molecular weight: 43500), DMS-S35 (molecular weight: 49000), DMS-S38 (molecular weight: 58000), DMS-S42 (molecular weight: 77000), or PDS-9931 (molecular weight: 1000 to 1400)) of silanol-terminated polydimethylsiloxane made by Gelest Inc.

The siloxane prepolymer (a-3) can be used alone or in multiple combinations.

Silica Particle (a-4)

The average particle size of the silica particle (a-4) is not particularly limited. The average particle size ranges from 2 nm to 250 nm, preferably 5 nm to 200 nm, and more preferably 10 nm to 100 nm.

Specific examples of the silica particle include, but are not limited to, a commercial product made by JGC Catalysts & Chemicals Co., Ltd. (such as OSCAR 1132 (particle size: 12 nm; dispersant: methanol), OSCAR 1332 (particle size: 12 nm; dispersant: n-propanol), OSCAR 105 (particle size: 60 nm; dispersant: γ-butyrolactone), or OSCAR 106 (particle size: 120 nm; dispersant: diacetone alcohol) . . . etc.); a commercial product made by Fuso Chemical Co. (such as Quartron PL-1-IPA (particle size: 13 nm; dispersant: isopropyl alcohol), Quartron PL-1-TOL (particle size: 13 nm; dispersant: toluene), Quartron PL-2L-PGME (particle size: 18 nm; dispersant: propylene glycol monomethyl ether), or Quartron PL-2L-MEK (particle size: 18 nm; dispersant: methyl ethyl ketone)); or a commercial product made by Nissan Chemical Company (such as IPA-ST (particle size: 12 nm; dispersant: isopropyl alcohol), EG-ST (particle size: 12 nm; dispersant: ethylene glycol), IPA-ST-L (particle size: 45 nm; dispersant: isopropyl alcohol), or IPA-ST-ZL (particle size: 100 nm; dispersant: isopropyl alcohol)). The silica particle can be used alone or in multiple combinations.

### Reaction Steps and Conditions of Polycondensation

In general, the polycondensation reaction is performed via the following steps: a solvent or water is added in the monomer component to synthesize the polysiloxane (A), or a catalyst can be optionally added, and the mixture is heated and stirred under 50° C. to 150° C. for 0.5 hours to 120 hours, and a byproduct (such as alcohol or water) can be further removed via distillation.

The solvent used in the polycondensation reaction is not particularly limited, and the solvent can be the same or different from the solvent (D) included in the photosensitive polysiloxane composition of the invention.

The solvent used in the polycondensation of the polysiloxane (A) preferably includes a ketone solvent. Specific examples of the ketone solvent include acetone, methyl ethyl ketone, methyl propyl ketone, methyl isopropyl ketone, methyl butyl ketone, methyl isobutyl ketone, methyl n-hexyl ketone, diethyl ketone, diisopropyl ketone, diisobutyl ketone, cyclopentanone, cyclohexanone, cycloheptanone, methyl cyclohexanone, acetyl acetone, diacetone alcohol, cyclohexen-1-one, or a combination thereof; wherein methyl isobutyl ketone, diisopropyl ketone, cyclohexanone, or a combination thereof is preferred. When the solvent used in the polycondensation of the polysiloxane (A) includes a ketone solvent, the adhesion of the photosensitive polysiloxane composition during development is better.

Based on a total amount of 100 g of the monomer component synthesizing the polysiloxane (A), the usage amount of the solvent is preferably 15 g to 1200 g; more preferably 20 g to 1100 g; and still more preferably 30 g to 1000 g.

Based on 1 mole of the hydrolyzable group of the monomer component synthesizing the polysiloxane (A), the water used in the polycondensation reaction (i.e., water used for hydrolysis) is 0.5 moles to 2 moles.

The catalyst used in the polycondensation reaction is not particularly limited, and is preferably selected from an acidic catalyst or a basic catalyst. Specific examples of the acidic catalyst include, but are not limited to, for instance, hydrochloric acid, nitric acid, sulfuric acid, hydrofluoric acid, oxalic acid, phosphoric acid, acetic acid, trifluoroacetic acid, formic acid, polybasic carboxylic acid or an anhydride thereof, or an ion exchange resin. Specific examples of the basic catalyst include, but are not limited to, for instance, diethylamine, triethylamine, tripropylamine, tributylamine, tripentylamine, trihexylamine, triheptylamine, trioctylamine, diethanolamine, triethanolamine, sodium hydroxide, potassium hydroxide, silane containing an amine group and having an alkoxy group, or an ion exchange resin.

Based on a total amount of 100 g of the monomer component synthesizing the polysiloxane (A), the usage amount of the catalyst is preferably 0.005 g to 15 g; more preferably 0.01 g to 12 g; and still more preferably 0.05 g to 10 g.

From the point of view of stability, the polysiloxane (A) preferably does not contain a byproduct (such as alcohol or water) and a catalyst. Therefore, purification can optionally be performed on the reaction mixture after the polycondensation reaction to obtain the polysiloxane (A). The method of purification is not particularly limited, and is preferably capable of diluting the reaction mixture with a hydrophobic solvent. Then, the hydrophobic solvent and the reaction mixture are transferred to a separation funnel. Next, the organic layer is washed with water several times, and the organic layer is concentrated with a rotary evaporator to remove the alcohol or water. Moreover, an ion exchange resin can be used to remove the catalyst.

The weight-average molecular weight of the polysiloxane (A) is 600 to 4000, preferably 800 to 4000. When the weight-average molecular weight of the polysiloxane (A) is in the above ranges, the adhesion of the photosensitive polysiloxane composition during development is better.

o-naphthoquinonediazidesulfonate (B)

The type of the o-naphthoquinonediazidesulfonate (B) is not particularly limited, and a general o-naphthoquinonediazidesulfonate can be used, provided the o-naphthoquinonediazidesulfonate is capable of achieving the objects claimed by the invention. The o-naphthoquinonediazidesulfonate (B) can be a completely esterified or partially esterified ester-based compound.

The o-naphthoquinonediazidesulfonate (B) is preferably prepared by reacting an o-naphthoquinonediazidesulfonic acid or a salt thereof and a hydroxy compound. The o-naphthoquinonediazidesulfonate (B) is more preferably prepared by reacting an o-naphthoquinonediazidesulfonic acid or a salt thereof and a polyhydroxy compound.

Specific examples of the o-naphthoquinonediazidesulfonic acid include, but are not limited to, for instance, o-naphthoquinonediazide-4-sulfonic acid, o-naphthoquinonediazide-5-sulfonic acid, or o-naphthoquinonediazide-6-sulfonic acid. Moreover, the salt of the o-naphthoquinonediazidesulfonic acid is, for instance, diazonaphthoquinone sulfonyl halide.

Specific examples of the hydroxy compound include, but are not limited to, a hydroxybenzophenone-based compound, a hydroxyaryl-based compound, a (hydroxyphenyl)hydrocarbon compound, other aromatic hydroxy compounds, or a combination of the compounds.

(1) Specific examples of the hydroxybenzophenone-based compound include, but are not limited to, for instance, 2,3,4-trihydroxybenzophenone, 2,4,4′-trihydroxybenzophenone, 2,4,6-trihydroxybenzophenone, 2,3,4,4′-tetrahydroxybenzophenone, 2,4,2′,4′-tetrahydroxybenzophenone, 2,4,6,3′,4′-pentahydroxybenzophenone, 2,3,4,2′,4′-pentahydroxybenzophenone, 2,3,4,2′,5′-pentahydroxybenzophenone, 2,4,5,3′,5′-pentahydroxybenzophenone, or 2,3,4,3′,4′,5′-hexahydroxybenzophenone.

(2) Specific examples of the hydroxyaryl-based compound include, but are not limited to, a hydroxyaryl-based compound represented by formula (4-1).

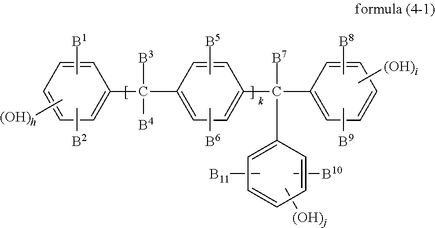

In formula (4-1), B¹ and B² each independently represent a hydrogen atom, a halogen atom, or a C₁ to C₆ alkyl group; B³, B⁴, and B⁷ each independently represent a hydrogen atom or a C₁ to C₆ alkyl group; B⁵, B⁶, B⁸, B⁹, B¹⁰, and B¹¹ each independently represent a hydrogen atom, a halogen atom, a C₁ to C₆ alkyl group, a C₁ to C₆ alkoxy group, a C₁ to C₆ alkenyl group, or a cycloalkyl group; h, i, and j each independently represent an integer of 1 to 3; and k represents 0 or 1.

Specifically, specific examples of the hydroxyaryl-based compound represented by formula (4-1) include, but are not limited to, tris(4-hydroxyphenyl)methane, bis(4-hydroxy-3,5-dimethylphenyl)-4-hydroxyphenylmethane, bis(4-hydroxy-3,5-dimethylphenyl)-3-hydroxyphenylmethane, bis(4-hydroxy-3,5-dimethylphenyl)-2-hydroxyphenylmethane, bis(4-hydroxy-2,5-dimethylphenyl)-4-hydroxyphenylmethane, bis(4-hydroxy-2,5-dimethylphenyl)-3-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3,5-dimethylphenyl)-2,4-dihydroxyphenylmethane, bis(4-hydroxy-2,5-dimethylphenyl)-2,4-dihydroxyphenylmethane, bis(4-hydroxyphenyl)-3-methoxy-4-hydroxyphenylmethane, bis(3-cyclohexyl-4-hydroxyphenyl)-3-hydroxyphenylmethane, bis(3-cyclohexyl-4-hydroxyphenyl)-2-hydroxyphenylmethane, bis(3-cyclohexyl-4-hydroxyphenyl)-4-hydroxyphenylmethane, bis(3-cyclohexyl-4-hydroxy-6-methylphenyl)-2-hydroxyphenylmethane, bis(3-cyclohexyl-4-hydroxy-6-methylphenyl)-3-hydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, bis(3-cyclohexyl-6-hydroxyphenyl)-3-hydroxyphenylmethane, bis(3-cyclohexyl-6-hydroxyphenyl)-4-hydroxyphenylmethane, bis(3-cyclohexyl-6-hydroxyphenyl)-2-hydroxyphenylmethane, bis(3-cyclohexyl-6-hydroxy-4-methylphenyl)-2-hydroxyphenylmethane, bis(3-cyclohexyl-6-hydroxy-4-methylphenyl)-4-hydroxyphenylmethane, bis(3-cyclohexyl-6-hydroxy-4-methylphenyl)-3,4-dihydroxyphenylmethane, 1-[1-(4-hydroxyphenyl)isopropyl]-4-[1,1-bis(4-hydroxyphenyl)ethyl]benzene, 1-[1-(3-methyl-4-hydroxyphenyl)isopropyl]-4-[1,1-bis(3-methyl-4-hydroxyphenyl)ethyl]benzene, or a combination of the compounds.

(3) Specific examples of the (hydroxyphenyl)hydrocarbon compound include, but are not limited to, a (hydroxyphenyl)hydrocarbon compound represented by formula (4-2).

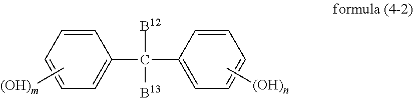

In formula (4-2), B¹² and B¹³ each independently represent a hydrogen atom or a C₁ to C₆ alkyl group; and m and n each independently represent an integer of 1 to 3.

Specifically, specific examples of the (hydroxyphenyl)hydrocarbon compound represented by formula (4-2) include, but are not limited to, for instance, 2-(2,3,4-trihydroxyphenyl)-2-(2′,3′,4′-trihydroxyphenyl)propane, 2-(2,4-dihydroxyphenyl)-2-(2′,4′-dihydroxyphenyl)propane, 2-(4-hydroxyphenyl)-2-(4′-hydroxyphenyl)propane, bis(2,3,4-trihydroxyphenyl)methane, or bis(2,4-dihydroxyphenyl)methane.

(4) Specific examples of the other aromatic hydroxy compounds include, but are not limited to, for instance, phenol, p-methoxyphenol, dimethylphenol, hydroquinone, bisphenol A, naphthol, catechol, 1,2,3-pyrogallol monomethyl ether, 1,2,3-pyrogallol-1,3-dimethyl ether, 3,4,5-trihydroxybenzoic acid, or partially esterified or partially etherified 3,4,5-trihydroxybenzoic acid.

The hydroxy compound is preferably 1-[1-(4-hydroxyphenyl)isopropyl]-4-[1,1-bis(4-hydroxyphenyl)ethyl]benzene, 2,3,4-trihydroxybenzophenone, 2,3,4,4′-tetrahydroxybenzophenone, or a combination thereof. The hydroxy compound can be used alone or in multiple combinations.

The reaction of the o-naphthoquinonediazidesulfonic acid or a salt thereof and the hydroxy compound is generally performed in an organic solvent such as dioxane, N-pyrrolidone, or acetamide. Moreover, the above reaction is preferably performed in the presence of a basic condensing agent such as triethanolamine, alkali metal carbonate, or alkali metal bicarbonate.

The degree of esterification of the o-naphthoquinonediazidesulfonate (B) is preferably at least 50%. That is, based on a total amount of 100 mol % of the hydroxy group in the hydroxy compound, at least 50 mol % of the hydroxy group in the hydroxy compound is reacted in the esterification reaction with the o-naphthoquinonediazidesulfonic acid or a salt thereof. The degree of esterification of the o-naphthoquinonediazidesulfonate (B) is more preferably at least 60%.

Based on an usage amount of 100 parts by weight of the polysiloxane (A), the usage amount of the o-naphthoquinonediazidesulfonate (B) is 1 part by weight to 35 parts by weight; preferably 1 part by weight to 30 parts by weight; and more preferably 5 parts by weight to 30 parts by weight.

### Solvent (C)

The type of the solvent (C) is not particularly limited. The solvent (C) is, for instance, an alcoholic hydroxy group-containing compound or a carbonyl group-containing cyclic compound . . . etc.

Specific examples of the alcoholic hydroxy group-containing compound include, but are not limited to, acetol, 3-hydroxy-3-methyl-2-butanone, 4-hydroxy-3-methyl-2-butanone, 5-hydroxy-2-pentanone, 4-hydroxy-4-methyl-2-pentanone (also referred to as diacetone alcohol (DAA)), ethyl lactate, butyl lactate, propylene glycol monomethyl ether, propylene glycol monoethyl ether (PGEE), propylene glycol monomethyl ether acetate (PGMEA), propylene glycol mono-n-propyl ether, propylene glycol mono-n-butyl ether, propylene glycol mono-t-butyl ether, 3-methoxy-1-butanol, 3-methyl-3-methoxy-1-butanol, or a combination thereof. It should be mentioned that, the alcoholic hydroxy group-containing compound is preferably DAA, ethyl lactate, PGEE, PGMEA, or a combination thereof. The alcoholic hydroxy group-containing compound can be used alone or in multiple combinations.

Specific examples of the carbonyl group-containing cyclic compound include, but are not limited to, for instance, γ-butyrolactone, γ-valerolactone, δ-valerolactone, propylene carbonate, N-methyl pyrrolidone, cyclohexanone, or cycloheptanone. It should be mentioned that, the cyclic compound containing a carbonyl group is preferably γ-butyrolactone, N-methyl pyrrolidone, cyclohexanone, or a combination thereof. The carbonyl group-containing cyclic compound can be used alone or in multiple combinations.

The alcoholic hydroxy group-containing compound can be used in combination with the carbonyl group-containing cyclic compound, and the weight ratio thereof is not particularly limited. The weight ratio of the alcoholic hydroxy group-containing compound and the carbonyl group-containing cyclic compound is preferably 99/1 to 50/50, more preferably 95/5 to 60/40. It should be mentioned that, in the solvent (C), when the weight ratio of the alcoholic hydroxy group-containing compound and the carbonyl group-containing cyclic compound is 99/1 to 50/50, the unreacted silanol group (Si—OH) in the polysiloxane (A) is not readily reacted in a condensation reaction and storage stability is therefore reduced. Moreover, since the compatibility of the alcoholic hydroxy group-containing compound and the carbonyl group-containing cyclic compound with the o-naphthoquinonediazidesulfonate (B) is good, the whitening phenomenon does not readily occur when the alcoholic hydroxy group-containing compound and the carbonyl group-containing cyclic compound are coated into a film. As a result, the transparency of the protective film can be retained.

Without impairing the effect of the invention, the solvent (C) can also contain other solvents. The other solvents are, for instance: (1) an ester such as ethyl acetate, n-propyl acetate, isopropyl acetate, n-butyl acetate, isobutyl acetate, propylene glycol monomethyl ether acetate, 3-methoxy-1-butyl acetate, or 3-methyl-3-methoxy-1-butyl acetate; (2) a ketone such as acetone, methyl ethyl ketone, methyl propyl ketone, methyl isopropyl ketone, methyl butyl ketone, methyl isobutyl ketone, methyl n-hexyl ketone, diethyl ketone, diisopropyl ketone, diisobutyl ketone, cyclopentanone, cyclohexanone, cycloheptanone, methyl cyclohexanone, acetyl acetone, diacetone alcohol, or cyclohexen-1-one; or (3) an ether such as diethyl ether, diisopropyl ether, di-n-butyl ether, or diphenyl ether.

The solvent (C) can be used alone or in multiple combinations.

Based on an usage amount of 100 parts by weight of the polysiloxane (A), the usage amount of the solvent (C) is 100 parts by weight to 1200 parts by weight; preferably 150 parts by weight to 1000 parts by weight; and more preferably 150 parts by weight to 900 parts by weight.

### Additive (D)

An additive (D) can optionally be further added to the photosensitive polysiloxane composition of the invention. Specifically, the additive (D) is, for instance, a sensitizer, an adhesion auxiliary agent, a surfactant, a solubility promoter, a defoamer, or a combination thereof.

The type of the sensitizer is not particularly limited. The sensitizer is preferably a phenolic hydroxy group-containing compound, wherein specific examples of the phenolic hydroxy group-containing compound include, but are not limited to, a trisphenol-type compound, a bisphenol-type compound, a polynuclear-branched compound, a condensation-type phenol compound, polyhydroxy benzophenone, or a combination of the compounds.
(1) Specific examples of the trisphenol-type compound include, but are not limited to, tris(4-hydroxyphenyl)methane, bis(4-hydroxy-3-methylphenyl)-2-hydroxyphenylmethane, bis(4-hydroxy-2,3,5-trimethylphenyl)-2-hydroxyphenylmethane, bis(4-hydroxy-3,5-dimethylphenyl)-4-hydroxyphenylmethane, bis(4-hydroxy-3,5-dimethylphenyl)-3-hydroxyphenylmethane, bis(4-hydroxy-3,5-methylphenyl)-2-hydroxyphenylmethane, bis(4-hydroxy-2,5-dimethylphenyl)-4-hydroxyphenylmethane, bis(4-hydroxy-2,5-dimethylphenyl)-3-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-2,5-dimethylphenyl)-2,4-dihydroxyphenylmethane, bis(4-hydroxyphenyl)-3-methoxy-4-hydroxyphenylmethane, bis(5-cyclohexyl-4-hydroxy-2-methylphenyl)-4-hydroxyphenylmethane, bis(5-cyclohexyl-4-hydroxy-2-methylphenyl)-3-hydroxyphenylmethane, bis(5-cyclohexyl-4-hydroxy-2-methylphenyl)-2-hydroxyphenylmethane, or bis(5-cyclohexyl-4-hydroxy-2-methylphenyl)-3,4-dihydroxyphenylmethane.
(2) Specific examples of the bisphenol-type compound include, but are not limited to, for instance, bis(2,3,4-trihydroxyphenyl)methane, bis(2,4-dihydroxyphenyl)methane, 2,3,4-trihydroxyphenyl-4′-hydroxyphenylmethane, 2-(2,3,4-trihydroxyphenyl)-2-(2′,3′,4′-trihydroxyphenyl)propane, 2-(2,4-dihydroxyphenyl)-2-(2′,4′-dihydroxyphenyl)propane, 2-(4-hydroxyphenyl)-2-(4′-hydroxyphenyl)propane, 2-(3-fluoro-4-hydroxyphenyl)-2-(3′-fluoro-4′-hydroxyphenyl)propane, 2-(2,4-dihydroxyphenyl)-2-(4′-hydroxyphenyl)propane, 2-(2,3,4-trihydroxyphenyl)-2-(4′-hydroxyphenyl)propane, or 2-(2,3,4-trihydroxyphenyl)-2-(4′-hydroxy-3′,5′-dimethylphenyl)propane.
(3) Specific examples of the polynuclear-branched compound include, but are not limited to, for instance, 1-[1-(4-hydroxyphenyl)isopropyl]-4-[1,1-bis(4-hydroxyphenyl)ethyl]benzene or 1-[1-(3-methyl-4-hydroxyphenyl)isopropyl]-4-[1,1-bis(3-methyl-4-hydroxyphenyl)ethyl]benzene.
(4) Specific examples of the condensation-type phenol compound include, but are not limited to, for instance, 1,1-bis(4-hydroxyphenyl)cyclohexane.
(5) Specific examples of the polyhydroxy benzophenone include, but are not limited to, for instance, 2,3,4-trihydroxybenzophenone, 2,4,4′-trihydroxybenzophenone, 2,4,6-trihydroxybenzophenone, 2,3,4-trihydroxy-2′-methylbenzophenone, 2,3,4,4′-tetrahydroxybenzophenone, 2,4,2′,4′-tetrahydroxybenzophenone, 2,4,6,3′,4′-pentahydroxybenzophenone, 2,3,4,2′,4′-pentahydroxybenzophenone, 2,3,4,2′,5′-pentahydroxybenzophenone, 2,4,6,3′,4′,5′-hexahydroxybenzophenone, or 2,3,4,3′,4′,5′-hexahydroxybenzophenone.

Based on an usage amount of 100 parts by weight of the polysiloxane (A), the usage amount of the sensitizing agent is 5 parts by weight to 50 parts by weight; preferably 8 parts by weight to 40 parts by weight; and more preferably 10 parts by weight to 35 parts by weight.

Specific examples of the adhesion auxiliary agent include, for instance, a melamine compound and a silane compound. The function of the adhesion auxiliary agent is to increase the adhesion between a protective film formed by the photosensitive polysiloxane composition and a protected element.

Specific examples of commercial products of melamine include, for instance, Cymel-300 or Cymel-303 . . . etc. made by Mitsui Chemicals or MW-30MH, MW-30, MS-11, MS-001, MX-750, or MX-706 . . . etc. made by Sanwa Chemical.

When a melamine compound is used as the adhesion auxiliary agent, based on an usage amount of 100 parts by weight of the polysiloxane (A), the usage amount of the melamine compound is 0 parts by weight to 20 parts by weight, preferably 0.5 parts by weight to 18 parts by weight, and more preferably 1 part by weight to 15 parts by weight.

Specific examples of the silane compound include, for instance, vinyltrimethoxysilane, vinyltriethoxysilane, 3-acryoyloxypropyltrimethoxysilane, vinyltris(2-methoxyethoxy) silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropyldimethylmethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane, 3-mercaptopropyltrimethoxysilane, or a commercial product (such as KBM403) made by Shin-Etsu Chemical Co.

When a silane-based compound is used as the adhesion auxiliary agent, based on an usage amount of 100 parts by weight of the polysiloxane (A), the usage amount of the silane-based compound is 0 parts by weight to 2 parts by weight, preferably 0.05 parts by weight to 1 part by weight, and more preferably 0.1 parts by weight to 0.8 parts by weight.

Specific examples of the surfactant include an anionic surfactant, a cationic surfactant, a nonionic surfactant, an amphoteric surfactant, a polysiloxane surfactant, a fluorine surfactant, or a combination thereof.

Specific examples of the surfactant include, but are not limited to, for instance, (1) a polyoxyethylene alkyl ether such as polyoxyethylene lauryl ether; (2) a polyoxyethylene alkyl phenyl ether such as polyoxyethylene octylphenyl ether or polyoxyethylene nonylphenyl ether; (3) a polyethylene glycol diester such as polyethylene glycol dilaurate or polyethylene glycol distearate; (4) a sorbitan fatty acid ester; (5) a fatty acid-modified poly ester; and (6) a tertiary amine-modified polyurethane. Specific examples of commercial products of the surfactant include KP (made by Shin-Etsu Chemical), SF-8427 (made by Dow Corning Toray Silicone Co., Ltd.), Polyflow (made by Kyoeisha Oil Chemical Co., Ltd.), F-Top (made by Tochem Products Co., Ltd.), Megaface (made by DIC), Fluorade (made by Sumitomo 3M Ltd.), Surflon (made by Asahi Glass), SINOPOL E8008 (made by Sino-Japan Chemical Co., Ltd.), F-475 (made by DIC), or a combination thereof.

Based on an usage amount of 100 parts by weight of the polysiloxane (A), the usage amount of the surfactant is 0.5 parts by weight to 50 parts by weight; preferably 1 part by weight to 40 parts by weight; and more preferably 3 parts by weight to 30 parts by weight.

Specific examples of the defoamer include, for instance, Surfynol MD-20, Surfynol MD-30, EnviroGem AD01, EnviroGem AE01, EnviroGem AE02, Surfynol DF110D, Surfynol 104E, Surfynol 420, Surfynol DF37, Surfynol DF58, Surfynol DF66, Surfynol DF70, and Surfynol DF210 (made by Air products). Based on a total amount of 100 parts by weight of the polysiloxane (A), the usage amount of the defoamer is 1 part by weight to 10 parts by weight; preferably 2 parts by weight to 9 parts by weight; and more preferably 3 parts by weight to 8 parts by weight.

Specific examples of the solubility promoter include N-hydroxydicarboxylic imide and a phenolic hydroxy group-containing compound. The solubility promoter is, for instance, the phenolic hydroxy group-containing compound used in the o-naphthoquinonediazidesulfonate (B). Based on an usage amount of 100 parts by weight of the polysiloxane (A), the usage amount of the dissolution accelerator is 1 part by weight to 20 parts by weight; preferably 2 parts by weight to 15 parts by weight; and more preferably 3 parts by weight to 10 parts by weight.

### <Preparation Method of Photosensitive Polysiloxane Composition>

The photosensitive polysiloxane composition of the invention is a positive-type photosensitive composition. A method that can be used to prepare the photosensitive polysiloxane composition includes, for instance: placing and stirring the polysiloxane (A), the o-naphthoquinonediazidesulfonate (B), and the solvent (C) in a stirrer such that the components are uniformly mixed into a solution state, and the additive (D) can also be added when needed. After the mixture is uniformly mixed, the photosensitive polysiloxane composition in solution state can be obtained.

### <Forming Method of Protective Film and Element Having the Protective Film>

The invention further provides a protective film formed by coating the above photosensitive polysiloxane composition on an element, and then performing pre-bake, exposure, development, and post-bake.

The invention further provides an element having a protective film, including an element and the above protective film, wherein the protective film covers the element. Specifically, the element having a protective film is, for instance, the core material or a covering material of a planarizing film, an interlayer insulating film, or an optical waveguide used in a liquid crystal display element and an organic electroluminescent display.

The forming method of the protective film is described in detail below. The method includes, in order: forming a pre-baked coating film using the photosensitive polysiloxane composition, performing patterning exposure on the pre-baked coating film, removing the unexposed region via alkali development to form a pattern, and performing a post-bake treatment to form the protective film.

### Forming of Pre-Baked Coating Film

The photosensitive polysiloxane composition in solution state is coated on a protected element (substrate hereinafter) by a coating method such as spin coating, cast coating, or roll coating to form a coating film.

The substrate can be a glass used in a liquid crystal display apparatus such as an alkali-free glass, soda-lime glass, hard glass (Pyrex glass), silica glass, such glasses with a transparent conductive film attached thereto, or a substrate (such as a silicon substrate) used in a photoelectric conversion apparatus (such as a solid imaging apparatus).

After the coating film is formed, most of the organic solvent of the photosensitive polysiloxane composition is removed by a method of reduced pressure drying. Next, the remaining organic solvent is completely removed by a pre-bake method, such that a pre-baked coating film is formed.

The operating conditions of the reduced pressure drying and pre-bake may be different based on the type and the mix ratio of each component. In general, drying under reduced pressure is performed at a pressure of 0 Torrs to 200 Torrs for 1 second to 60 seconds, and pre-bake is performed at a temperature of 70° C. to 110° C. for 1 minute to 15 minutes.

### Patterning Exposure

The above pre-baked coating film is exposed with a photomask having a specific pattern. The light used in the exposure process is preferably an ultraviolet light such as a g-ray, an h-ray, or an i-ray. In addition, the equipment used to provide the ultraviolet light can be a/an (ultra-)high pressure mercury lamp or a metal halide lamp.

### Development

The exposed pre-baked coating film is immersed in a developing solution at a temperature in the range of 23±2° C. and developed for about 15 seconds to 5 minutes to remove the unwanted portion of the exposed pre-baked coating film. As a result, a semifinished product of a protective film having a specific pattern can be formed on the substrate. Specific examples of the developing solution include, but are not limited to, an alkali compound such as sodium hydroxide, potassium hydroxide, sodium carbonate, sodium hydrogen carbonate, potassium carbonate, potassium hydrogen carbonate, sodium silicate, sodium methyl silicate, ammonia solution, ethylamine, diethylamine, dimethylethylanolamine, tetramethylammonium hydroxide (TMAH), tetraethylammonium hydroxide, choline, pyrrole, piperidine, or 1,8-diazabicyclo-[5.4.0]-7-undecene.

It should be mentioned that, if the concentration of the developing solution is too high, then the specific pattern is damaged or the resolution of the specific pattern is poor; and if the concentration is too low, then the development is poor, thus causing the specific pattern to not be formed or a portion of the composition residue to be exposed. Therefore, the concentration affects the subsequent forming of the exposed specific pattern of the photosensitive polysiloxane composition. The range of concentration of the developing solution is preferably 0.001 wt % to 10 wt %, more preferably 0.005 wt % to 5 wt %, and even more preferably 0.01 wt % to 1 wt %. A developing solution of 2.38 wt % of TMAH is used in the embodiments of the invention. It should be mentioned that, even if a developing solution having lower concentration is used, the photosensitive polysiloxane composition of the invention can still form a good finer pattern.

### Post-Bake Treatment

The substrate is washed with water (wherein the substrate has the semifinished product of the protective film having a predetermined pattern thereon) to remove the unwanted portion of the exposed pre-baked coating film. Then, the semifinished product of the protective film having a predetermined pattern is dried with compressed air or compressed nitrogen. Lastly, a post-bake treatment is performed on the semifinished product of the protective film having a predetermined pattern with a heating apparatus such as a hot plate or an oven. The heating temperature is set between 100° C. and 250° C., wherein when a hot plate is used, the heating time is 1 minute to 60 minutes, and when an oven is used, the heating time 5 minutes to 90 minutes. Accordingly, the pattern of the semifinished product of the protective film having a predetermined pattern can be fixed to form the protective film.

The following examples are used to further describe the invention. However, it should be understood that, the examples are only exemplary, and are not intended to limit the implementation of the invention.

### Synthesis Examples and Comparative Synthesis Examples of Polysiloxane (A)

Synthesis example A-1 to synthesis example A-12 of the polysiloxane (A) are described below:

### Synthesis Example A-1

In a three-necked flask having a volume of 500 ml, 0.40 moles of titanium isobutoxide (hereinafter TBT), 0.35 moles of phenyltrimethoxysilane (hereinafter PTMS), 0.25 moles of 3-(triethoxysilyl)propyl succinic anhydride (hereinafter GF-20), and 280 g of methyl isobutyl ketone (hereinafter MIBK) were added, and the mixture was stirred under room temperature while an aqueous solution of oxalic acid (0.30 g of oxalic acid dissolved in 50 g of water) was added within 30 minutes. Then, the three-necked flask was immersed in an oil bath at 30° C. and stirred for 30 minutes. Next, the temperature of the oil bath was raised to 60° C. within 30 minutes. When the temperature of the solution was reduced to 105° C. (i.e., reaction temperature), the solution was continuously heated and stirred to perform polymerization for 3 hours (i.e., polycondensation time). Then, the solvent and the by-products were removed by a distillation method to obtain a polysiloxane A-1. The type and the usage amount of the components of the polysiloxane A-1 are as shown in Table 1.

### Synthesis Example A-2 to Synthesis Example A-9 and Synthesis Example A-11

The polysiloxane (A) (i.e., polysiloxane A-2 to polysiloxane A-9 and synthesis example A-11) of synthesis example A-2 to synthesis example A-9 and synthesis example A-11 was prepared with the same steps as synthesis example A-1, and the difference thereof is: the monomer composition synthesizing the polysiloxane (A), the solvent, the catalyst, and the usage amount, reaction temperature, and polycondensation time thereof were changed (as shown in Table 1).

### Synthesis Example A-10

In a three-necked flask having a volume of 500 ml, 0.50 moles of methyltrimethoxysilane (hereinafter MTMS), 0.45 moles of phenyltrimethoxysilane (hereinafter PTMS), 0.05 moles of 3-(trimethoxysilyl)propyl glutaric anhydride (hereinafter TMSG), and 250 g of propylene glycol monoethyl ether (hereinafter PGEE) were added, and the mixture was stirred under room temperature while an aqueous solution of oxalic acid (0.40 g of oxalic acid dissolved in 75 g of water) was added within 30 minutes. Then, the three-necked flask was immersed in an oil bath at 30° C. and stirred for 30 minutes. Next, the temperature of the oil bath was raised to 120° C. within 30 minutes. When the temperature of the solution was reduced to 105° C. (i.e., reaction temperature), the solution was continuously heated and stirred to perform polymerization for 5 hours (i.e., polycondensation time). Then, the solvent and the by-products were removed by a distillation method to obtain a polysiloxane A-10. The type and the usage amount of the components of the polysiloxane A-10 are as shown in Table 1.

### Synthesis Example A-12

In a three-necked flask having a volume of 500 ml, 0.30 moles of methyltrimethoxysilane (hereinafter MTMS), 0.65 moles of phenyltrimethoxysilane (hereinafter PTMS), 0.05 moles of 3-(triethoxysilyl)propyl succinic anhydride (hereinafter GF-20), 60 g of a dispersion (Optolake TR-513, made by Catalysts & Chemicals Industries Co., Ltd.) of a silicon oxide-titanium oxide composite particle, and 220 g of propylene glycol monoethyl ether (PGEE) were added, and the mixture was stirred under room temperature while an aqueous solution of oxalic acid (0.40 g of oxalic acid dissolved in 75 g of water) was added within 30 minutes. Then, the flask was immersed in an oil bath at 30° C. and stirred for 30 minutes. Next, the temperature of the oil bath was raised to 120° C. within 30 minutes. When the temperature of the solution was reduced to 105° C. (i.e., reaction temperature), the solution was continuously heated and stirred to perform polymerization for 6 hours (i.e., polycondensation time). Then, the solvent was removed by a distillation method to obtain a polysiloxane A-12.

### Synthesis Example A-13

In a three-necked flask having a volume of 500 ml, 0.30 moles of methyltrimethoxysilane (hereinafter MTMS), 0.65 moles of phenyltrimethoxysilane (hereinafter PTMS), 0.05 moles of 3-(triethoxysilyl)propyl succinic anhydride (hereinafter GF-20), 2 g of di-i-propoxy bis(ethyl acetoacetato)titanium, and 220 g of propylene glycol monoethyl ether (hereinafter PGEE) were added, and the mixture was stirred under room temperature while an aqueous solution of oxalic acid (0.40 g of oxalic acid dissolved in 75 g of water) was added within 30 minutes. Then, the flask was immersed in an oil bath at 30° C. and stirred for 30 minutes. Next, the temperature of the oil bath was raised to 120° C. within 30 minutes. When the temperature of the solution was reduced to 105° C. (i.e., reaction temperature), the solution was continuously heated and stirred to perform polymerization for 6 hours (i.e., polycondensation time). Then, the solvent was removed by a distillation method to obtain polysiloxane A-13.

The compounds corresponding to the abbreviations in Table 1 are as shown below.

### Abbreviation Compound

TBT Titanium isobutoxide
(a-1-1) Titanium 2-ethylhexyloxide
(a-1-2) Dibutoxy bis[[[2-(butoxycarbonyl)phenyl]carbonyl]oxy]titanium
TPT dimer Titanium propoxide dimer
MTMS Methyltrimethoxysilane
DMDMS Dimethyldimethoxysilane
PTMS Phenyltrimethoxysilane
PTES Phenyltriethoxysilane
GF-20 3-(triethoxysilyl)propyl succinic anhydride
TMSG 3-(trimethoxysilyl)propyl glutaric anhydride
TMSOX-D 2-oxetanylbutoxypropyltrimethoxysilane
TESOX-D 2-oxetanylbutoxypropyltriethoxysilane
DMS-S27 Silanol-terminated polysiloxane, made by Gelest Inc.
PGEE Propylene glycol monoethyl ether
DAA Diacetone alcohol (i.e., 4-hydroxy-4-methyl-2-pentanone)
MIBK Methyl isobutyl ketone
DIPK Di-isopropylketone
CHK Cyclohexanone
Water DI water
Oxalic acid Oxalic acid

TABLE 1

| | | Synthesis example | | | | | | | | | | |
|---|---|---|---|---|---|---|---|---|---|---|---|---|
| Unit: moles | | A-1 | A-2 | A-3 | A-4 | A-5 | A-6 | A-7 | A-8 | A-9 | A-10 | A-11 |
| Titanium- | TBT | 0.40 | — | — | — | — | — | 0.50 | — | — | — | 1.00 |
| containing | (a-1-1) | — | 0.30 | — | — | 0.50 | — | — | 0.30 | 0.20 | — | — |
| compound | (a-1-2) | — | — | 0.20 | — | — | 0.35 | 0.10 | — | — | — | — |
| (a-1) | TPT | — | — | — | 0.10 | — | — | — | — | 0.10 | — | — |
| | dimer | | | | | | | | | | | |
| Silane monomer | MTMS | — | 0.60 | — | — | — | — | 0.30 | — | — | 0.50 | — |
| (a-2) | DMDMS | — | — | 0.40 | — | — | 0.20 | — | 0.29 | — | — | — |
| | PTMS | 0.35 | — | — | 0.85 | — | 0.30 | — | 0.25 | 0.70 | 0.45 | — |
| | PTES | — | — | 0.40 | — | 0.30 | — | — | — | — | — | — |
| | GF-20 | 0.25 | — | — | — | — | 0.15 | 0.10 | — | — | — | — |
| | TMSG | — | — | — | 0.05 | — | — | — | 0.15 | — | 0.05 | — |
| | TMSOX-D | — | 0.10 | — | — | — | — | — | — | — | — | — |
| | TESOX-D | — | — | — | — | 0.20 | — | — | — | — | — | — |
| Siloxane | DMS-S27 | — | — | — | — | — | — | — | 0.01 | — | — | — |
| prepolymer (a-3) | | | | | | | | | | | | |
| Solvent (g) | PGEE | — | 200 | 260 | 50 | — | — | — | 280 | — | 250 | — |
| | DAA | — | 50 | — | — | — | — | 200 | — | — | — | 50 |
| | MIBK | 280 | — | — | — | 50 | 200 | — | — | 250 | — | 200 |
| | DIPK | — | — | — | 200 | — | — | 80 | — | — | — | — |
| | CHK | — | — | — | — | 200 | 50 | — | — | — | — | — |
| Catalyst (g) | Water | 50 | 65 | 50 | 45 | 50 | 50 | 60 | 60 | 60 | 75 | 50 |
| | Oxalic | 0.30 | 0.40 | 0.35 | 0.30 | 0.35 | 0.30 | 0.35 | 0.35 | 0.35 | 0.40 | 0.40 |
| | acid | | | | | | | | | | | |

| | | | | | | | | | | | |
|---|---|---|---|---|---|---|---|---|---|---|---|
| Reaction temperature (° C.) | 60 | 60 | 60 | 60 | 60 | 65 | 60 | 60 | 60 | 105 | 60 |
| Polycondensation time | 3 | 3 | 4 | 3.5 | 2.5 | 2 | 3 | 3 | 3 | 5 | 3 |
| (hours) | | | | | | | | | | | |
| Weight-average molecular | 1839 | 2228 | 5483 | 3593 | 642 | 572 | 2065 | 1975 | 2032 | 7463 | 1275 |
| weight | | | | | | | | | | | |

### Examples and Comparative Examples of Photosensitive Polysiloxane Composition and Protective Film

Example 1 to example 8 and comparative example 1 to comparative example 6 of the photosensitive polysiloxane composition and the protective film are described below:

### Example 1

### a. Preparation of Photosensitive Polysiloxane Composition

100 parts by weight of the polysiloxane A-1, 1 part by weight of an o-naphthoquinonediazidesulfonate (B-1) formed by 1-[1-(4-hydroxyphenyl)isopropyl]-4-[1,1-bis(4-hydroxyphenyl)ethyl]benzene and o-naphthoquinonediazide-5-sulfonic acid, and 0.1 parts by weight of a SF-8427 (D-1) were added in 100 parts by weight of a propylene glycol monomethyl ether acetate (PGMEA) (C-1), and after the mixture was uniformly stirred via a shaking-type stirrer, the photosensitive polysiloxane composition of example 1 was obtained. The photosensitive polysiloxane composition of example 1 was evaluated via the evaluation methods below, and the results thereof are as shown in Table 2.

### b. Forming of Protective Film

The photosensitive polysiloxane composition was coated on a glass substrate having a size of 100×100×0.7 mm³ via a method of spin coating to form a coating film. Next, the coating film was pre-baked under 100° C. for 2 minutes to form a pre-baked coating film having a thickness of about 2 μm. Then, a photomask for positive photoresist was disposed between an exposure machine and the pre-baked coating film, and patterning exposure was performed on the pre-baked coating film via 300 mJ/cm² of ultraviolet (model of exposure machine: AG500-4N, made by M&R Nano Technology). Then, the substrate having the exposed pre-baked coating film thereon was developed with a 2.38% aqueous solution of tetramethylammonium hydroxide (TMAH) at 23° C. for 60 seconds to remove the unexposed portion of the coating film on the glass substrate. Next, the glass substrate was washed with water. Then, the exposed and developed pre-baked coating film was irradiated with 200 mJ/cm² of energy via an exposure machine. Then, post-bake was performed on the pre-baked coating film via an oven under 230° C. for 60 minutes to form a protective film on the glass substrate.

### Example 2 to Example 8

The photosensitive polysiloxane compositions and the protective films of example 2 to example 8 were respectively prepared by the same steps as example 1, and the difference thereof is: the type of the components and the usage amount thereof were changed, as shown in Table 2. The photosensitive polysiloxane composition of each of examples 2 to 12 was evaluated with the evaluation methods below, and the results thereof are as shown in Table 2.

### Comparative Example 1 to Comparative Example 6

The photosensitive polysiloxane compositions of comparative example 1 to comparative example 6 were respectively prepared by the same steps as example 1, and the difference thereof is: the type of the components and the usage amount thereof were changed, as shown in Table 3. The photosensitive polysiloxane compositions of comparative example 1 to comparative example 6 were evaluated with each evaluation method below, and the results thereof are as shown in Table 3.

The compounds corresponding to the abbreviations in Table 2 and Table 3 are as shown below.

### Abbreviation Compound

A-1 Polysiloxane A-1
A-2 Polysiloxane A-2
A-3 Polysiloxane A-3
A-4 Polysiloxane A-4
A-5 Polysiloxane A-5
A-6 Polysiloxane A-6
A-7 Polysiloxane A-7
A-8 Polysiloxane A-8
A-9 Polysiloxane A-9
A-10 Polysiloxane A-10
A-11 Polysiloxane A-11
A-12 Polysiloxane A-12
A-13 Polysiloxane A-13
B-1 o-naphthoquinonediazidesulfonate formed by 1-[1-(4-hydroxyphenyl)isopropyl]-4-[1,1-bis(4-hydroxyphenyl)ethyl]benzene and o-naphthoquinonediazide-5-sulfonic acid
B-2 o-naphthoquinonediazidesulfonate formed by 2,3,4-trihydroxybenzophenone and o-naphthoquinonediazide-5-sulfonic acid
C-1 Propylene glycol monomethyl ether acetate (PGMEA)
C-2 Diacetone alcohol (DAA) (i.e., 4-hydroxy-4-methyl-2-pentanone)
C-3 Cyclohexanone
D-1 SF-8427 (made by Dow Corning Toray Co., Ltd., surfactant)
D-2 Dispersion (Optolake TR-513, made by Catalysts & Chemicals Industries Co., Ltd.) of silicon oxide-titanium oxide composite particle
D-3 3-glycidoxypropyltrimethoxysilane (trade name: KBM403, made by Shin-Etsu Chemical Co., Ltd., adhesion auxiliary agent)

### Evaluation Methods

### a. Weight-Average Molecular Weight

The weight-average molecular weight (Mw) of the polysiloxane (A) was obtained via the calibration curve made from a known commercial standard styrene and measured via a gel permeation chromatography (GPC) analyzer (made by Waters Limited) having the two functions of differential index of refraction detection and light scattering detection.

### b. Adhesion During Development

The photosensitive polysiloxane composition was coated on a glass substrate via a method of spin coating to form a coating film. Next, the coating film was pre-baked under 100° C. for 2 minutes to form a pre-baked coating film having a thickness of about 2 μm. Then, a photomask (made by Nippon Filcon) of line and space was placed between the exposure machine and the pre-baked coating film, and exposure was performed via 300 mJ/cm² of ultraviolet (model of exposure machine: AG500-4N, made by M&R Nano Technology). Then, the substrate having the exposed pre-baked coating film thereon was developed with a 2.38% aqueous solution of tetramethylammonium hydroxide (TMAH) under 23° C. for 60 seconds to remove the unexposed portion of the coating film on the glass substrate. Then, after cleaning with pure water, the developable linewidth of the development pattern on the glass substrate was recorded. The evaluation criteria of developable linewidth are as shown below, wherein a smaller developable linewidth represents better adhesion during development.
⊚: developable linewidth≦12 μm;
◯: 12 μm<developable linewidth≦20 μm;
Δ: 20 μm<developable linewidth≦40 μm;
X: developable linewidth>40 μm.

TABLE 2

| Component | | Example | | | | | | | | | | |
|---|---|---|---|---|---|---|---|---|---|---|---|---|
| unit: parts by weight | | 1 | 2 | 3 | 4 | 5 | 6 | 7 | 8 | 9 | 10 | 11 |
| Polysiloxane (A) | A-1 | 100 | — | — | — | — | — | — | — | — | — | — |
| | A-2 | — | 100 | — | — | — | — | — | — | — | 80 | 50 |
| | A-3 | — | — | 100 | — | — | — | — | — | — | — | — |
| | A-4 | — | — | — | 100 | — | — | — | — | — | — | — |
| | A-5 | — | — | — | — | 100 | — | — | — | — | — | 50 |
| | A-6 | — | — | — | — | — | 100 | — | — | — | — | — |
| | A-7 | — | — | — | — | — | — | 100 | — | — | — | — |
| | A-8 | — | — | — | — | — | — | — | 100 | — | — | — |
| | A-9 | — | — | — | — | — | — | — | — | 100 | 20 | — |
| | A-10 | — | — | — | — | — | — | — | — | — | — | — |
| | A-11 | — | — | — | — | — | — | — | — | — | — | — |
| | A-12 | — | — | — | — | — | — | — | — | — | — | — |
| | A-13 | — | — | — | — | — | — | — | — | — | — | — |
| o-naphthoquinone- | B-1 | 1 | — | 5 | 10 | 30 | 15 | 10 | 25 | 35 | 20 | 10 |
| diazidesulfonate (B) | B-2 | — | 3 | — | — | — | — | 10 | — | — | — | 5 |
| Solvent (C) | C-1 | 100 | 300 | 500 | 300 | — | 500.0 | 1000 | 500 | 500 | 300 | 500 |
| | C-2 | — | — | — | 300 | — | — | — | 100 | — | — | — |
| | C-3 | — | — | — | — | 800 | — | 200 | — | — | — | — |
| Additive (D) | D-1 | 0.1 | — | 0.1 | — | — | — | — | — | — | — | — |
| | D-2 | — | — | — | — | — | — | — | — | — | — | — |
| | D-3 | — | — | 0.1 | — | — | — | — | — | — | — | 0.2 |

| | | | | | | | | | | | |
|---|---|---|---|---|---|---|---|---|---|---|---|
| Developing adhesion | ⊚ | ⊚ | ◯ | ⊚ | ⊚ | ⊚ | ⊚ | ⊚ | ⊚ | ⊚ | ⊚ |

TABLE 3

| Component | | Comparative example | | | | |
|---|---|---|---|---|---|---|
| unit: parts by weight | | 1 | 2 | 3 | 4 | 5 |
| Polysiloxane | A-1 | — | — | — | — | — |
| polymer (A) | A-2 | — | — | — | — | — |
| | A-3 | — | — | — | — | — |
| | A-4 | — | — | — | — | — |
| | A-5 | — | — | — | — | — |
| | A-6 | — | — | — | — | — |
| | A-7 | — | — | — | — | — |
| | A-8 | — | — | — | — | — |
| | A-9 | — | — | — | — | — |
| | A-10 | 100 | — | — | — | 100 |
| | A-11 | — | 100 | — | — | — |
| | A-12 | — | — | 100 | — | — |
| | A-13 | — | — | — | 100 | — |
| o-naphthoquinone- | B-1 | 3 | — | 5 | 10 | 10 |
| diazidesulfonate (B) | B-2 | — | 5 | — | — | — |
| Solvent (C) | C-1 | 500 | — | 500 | — | 800 |
| | C-2 | — | 500 | — | — | — |
| | C-3 | — | — | — | 500 | — |
| Additive (D) | D-1 | — | — | — | — | — |
| | D-2 | 50 | — | — | — | — |
| | D-3 | — | — | — | — | — |

| | | | | | |
|---|---|---|---|---|---|
| Developing adhesion | X | X | X | X | X |

### Evaluation Results

It can be known from Table 2 and Table 3 that, in comparison to the photosensitive polysiloxane compositions (example 1 to example 11) of the polysiloxane (A) having both the titanium-containing compound (a-1) and the silane monomer (a-2) represented by formula (2), the adhesion of the photosensitive polysiloxane compositions (comparative example 1 to comparative examples 3 to 5) containing the polysiloxane (A) but does not include both the titanium-containing compound (a-1) and the silane monomer (a-2) represented by formula (2) during development is poor. It can therefore be known that, when the monomer component synthesizing the polysiloxane (A) does not include the titanium-containing compound (a-1), the adhesion of the photosensitive polysiloxane composition during development is poor.

Moreover, when the monomer component synthesizing the polysiloxane (A) does not include the silane monomer (a-2) (comparative example 2), the photosensitive polysiloxane composition cannot be developed after exposure, which is unsatisfactory.

Moreover, when the monomer component synthesizing the polysiloxane (A) includes a silane monomer (examples 1, 2, 4 to 8, 10, and 11) containing an anhydride group or an epoxy group, the adhesion of the photosensitive polysiloxane composition during development is better. It can therefore be known that, when in the silane monomer (a-2), at least one of an alkyl group containing an anhydride group, an alkyl group containing an epoxy group, or an alkoxy group containing an epoxy group is present, the adhesion of the photosensitive polysiloxane composition during development is better.

When the solvent used in the polycondensation of the polysiloxane (A) includes a ketone solvent (examples 1, 4 to 7, 9, and 10), the adhesion of the photosensitive polysiloxane composition during development is better.

When the weight-average molecular weight of the polysiloxane (A) is 600 to 4000 (examples 1, 2, 4 to 5, 7 to 11), the adhesion of the photosensitive polysiloxane composition during development is better.

Based on the above, since the photosensitive polysiloxane composition of the invention contains a polysiloxane obtained via the polycondensation of a specific titanium-containing compound, the adhesion during development is good, and the photosensitive polysiloxane composition is suitable for forming a protective film, such as the core material or the covering material of a planarizing film, an interlayer insulating film, or an optical waveguide used in a liquid crystal display element and an organic electroluminescent display.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A photosensitive polysiloxane composition, comprising:
a polysiloxane (A);
an o-naphthoquinonediazidesulfonate (B); and
a solvent (C),
wherein the polysiloxane (A) is obtained via a polycondensation of a monomer component, wherein the monomer component comprises a titanium-containing compound (a-1) and a silane monomer (a-2) represented by formula (2),
the titanium-containing compound (a-1) is selected from the group consisting of a compound represented by formula (1-1) and a hydrolyzable titanium dimer,
Ti(R¹)ₐ(R²)₄₋ₐ formula (1-1)
in formula (1-1), R¹ each independently represents an organic group having an alkyl group, an aryl group, a halogenated alkyl group, a halogenated aryl group, an alkenyl group, an epoxy group, an acryloyl group, a methacryloyl group, a mercapto group, an amine group, or a cyano group, and the organic group is bonded with a titanium atom via a Ti—C bond; R² each independently represents an alkoxy group, an acyloxy group, or a halogen atom; a represents an integer of 0 to 2,
Si(R^{a})_{w}(OR^{b})_{4-w} formula (2)
in formula (2), R^{a} each independently represents a hydrogen atom, a C₁ to C₁₀ alkyl group, a C₂ to C₁₀ alkenyl group, a C₆ to C₁₅ aryl group, an alkyl group containing an anhydride group, an alkyl group containing an epoxy group, or an alkoxy group containing an epoxy group; R^{b} each independently represents a hydrogen atom, a C₁ to C₆ alkyl group, a C₁ to C₆ acyl group, or a C₆ to C₁₅ aryl group; w represents an integer of 1 to 3.

2. The photosensitive polysiloxane composition of claim 1, wherein in formula (2), at least one R^{a} represents an alkyl group containing an anhydride group, an alkyl group containing an epoxy group, or an alkoxy group containing an epoxy group.

3. The photosensitive polysiloxane composition of claim 1, wherein a solvent used in the polycondensation of the polysiloxane (A) comprises a ketone solvent.

4. The photosensitive polysiloxane composition of claim 1, wherein a weight-average molecular weight of the polysiloxane (A) is 600 to 4000.

5. The photosensitive polysiloxane composition of claim 1, wherein based on 100 parts by weight of the polysiloxane (A), a usage amount of the o-naphthoquinonediazidesulfonate (B) is 1 part by weight to 35 parts by weight, and a usage amount of the solvent (C) is 100 parts by weight to 1200 parts by weight.

6. A protective film formed by coating the photosensitive polysiloxane composition of claim 1 on an element, and then performing pre-bake, exposure, development, and post-bake.

7. An element having a protective film, comprising an element and the protective film of claim 6, wherein the protective film covers the element.
